(19) United States
(12) Patent Application Publication
(10) Pub. No.: US 2007/0085574 A1
(43) Pub. Date: Apr. 19, 2007

(54) Audio signal detection utilizing low power standby power supply

(76) Inventors: Atron Lo, Mississauga (CA); Jeliazko Stoyanov Batchvarov, Etobicoke (CA)

Correspondence Address: BERESKIN AND PARR, 40 KING STREET WEST, BOX 401, TORONTO, ON, M5H 3Y2, CA

(21) Appl. No.: 11/246,226

(22) Filed: Oct. 11, 2005

(51) Int. Cl. H03C 3/00

(52) U.S. Cl. 327/101

(57) ABSTRACT

A standby circuit generates a control signal for configuring a main power supply circuit to operate in one of a full operation mode and a standby operation mode. The standby circuit includes a standby power supply block and a control block. The standby power supply block produces a power supply signal for powering the control block. The control block receives a mode control signal that indicates the operation mode and automatically generates a coupling signal based on the mode indicated by the mode control signal. The control signal is based on the coupling signal.

### FIELD

The invention relates to electronic circuitry having a full operational mode and a low power dissipation standby mode.

### BACKGROUND

Some consumer electronic devices can operate in a full operation mode and a standby mode. In standby mode, these electronic devices operate in a non-fully functional state while waiting for an activation signal to indicate that the device is to return to full operation mode. However, while these devices are in standby mode they can waste significant power. The wasted power in standby mode can actually account for up to 10% of all residential power or 20 to 60 W per household in developed countries. This problem has become a worldwide concern and global energy conscious agencies such as the International Energy Agency, EPA, Energy Star and EU have proposed, implemented and/or endorsed energy conscious schemes such as the Global 1 Watt program. The Global lWatt program recommends that consumer electronic products operating in standby mode should consume less than 1 W of input power.

In an attempt to reduce standby power consumption, some devices may employ a Switched Mode Power Supply (SMPS) that is operated in burst mode by reducing operating frequency, skipping switching cycles, or reducing the duty cycle. Regardless of which approach is employed for implementing burst mode operation, there are several disadvantages. For instance, when the switching frequency and/or duty cycle of the SMPS is significantly reduced to reduce power consumption, the transformer in the SMPS is forced to operate at frequencies for which it is not optimized. This results in audible noise due to transformer “chatter” or “buzzing”. In addition, the reduced switching frequency and/or duty cycle produces large ripples in the output voltage of the SMPS. Accordingly, large filtering capacitors are typically required when the SMPS operates in burst mode operation.

Furthermore, to implement any of the topologies for burst mode operation, a more complicated or component intensive control scheme is usually required. Also, since the same power train is used for both the active and standby modes, and since the power train is optimized for full power operation, the power losses do not scale down in the standby mode. Therefore, it is difficult to achieve low standby power dissipation when the SMPS is operating in burst mode.

### SUMMARY

In one aspect, at least one embodiment of the invention provides an electronic device comprising an application circuit; a main power supply circuit coupled to a power source and the application circuit, the main power supply circuit operates in a full operation mode and a standby operation mode, wherein during the full operation mode the main power supply circuit provides a first power supply signal to the application circuit and during the standby mode the main power supply does not provide the first power supply signal to the application circuit; and, a standby circuit coupled to the main power supply circuit, the standby circuit provides a control signal to the main power supply circuit to configure the main power supply to operate in one of the full operation mode and the standby operation mode.

In some embodiments, the standby circuit can comprise a standby power supply block that provides a second power supply signal; a control block coupled to the standby power supply block to receive the second power supply signal, the control block receives a mode control signal that indicates the operation mode and generates a coupling signal based on the mode control signal and determines timing for applying the coupling signal; and, a coupling unit coupled to the control block and the main power supply block, the coupling unit generates the control signal based on the coupling signal.

In some embodiments, the control block can also receive an auxiliary control signal and is adapted to override the mode control signal and generate the coupling signal based on the auxiliary control signal.

In another aspect, at least one embodiment of the invention provides a standby circuit that generates a control signal for configuring a main power supply circuit to operate in one of a full operation mode and a standby operation mode. The standby circuit comprises a standby power supply block comprising a voltage reducer that receives a first supply voltage and produces a reduced voltage; a transformer having a primary winding and a secondary winding, the primary winding having first and second nodes, the first node of the primary winding receiving a switched version of the reduced voltage, and the secondary winding producing a power supply signal; a switching stage coupled to the primary winding of the transformer for providing an oscillation signal to switch the voltage across the primary winding based on a switching sequence; and, an oscillation control stage coupled to the voltage reducer and the switching stage, the oscillation control stage receives the reduced voltage and produces at least one oscillation control signal to control the switching of the switching stage, wherein the switching stage provides the oscillation signal as feedback to the oscillation control stage for altering the at least one oscillation control signal. The standby circuit further comprises a control block coupled to the standby power supply block to receive the power supply signal, the control block receives a mode control signal that indicates the operation mode and generates a coupling signal based on the mode indicated by the mode control signal, the control signal being based on the coupling signal.

In some cases, the first node of the primary winding of the transformer is coupled to the voltage reducer and the switching stage comprises a first transistor having a collector node, a base node and an emitter node, and a second transistor having a collector node, a base node and an emitter node, wherein the emitter nodes of the first and second transistors are coupled, the collector node of the first transistor is coupled to the second node of the primary winding of the transformer, and the collector node of the second transistor is coupled to the oscillation control stage and to ground, and wherein the oscillation control stage provides a first oscillation control signal to the base node of the first transistor and a second oscillation control signal to the base node of the second transistor.

In some cases, the oscillation control stage comprises a first resistor having first and second nodes, the first node being coupled to the output node of the voltage reducer to receive the reduced voltage and the second node being coupled to the base node of the first transistor for providing the first oscillation control signal; a capacitor having first and second nodes, the first node of the capacitor being coupled to the collector node of the first transistor and the second node of the capacitor being coupled to the base node of the second transistor; and, a second resistor having first and second nodes, the first node of the second resistor being coupled to the second node of the capacitor and to the base node of the second transistor to provide the second oscillation control signal, and the second node of the second resistor being coupled to the collector node of the second transistor and to ground.

In some cases, the first node of the primary winding of the transformer is coupled to the oscillation control stage and the second node of the primary winding of the transformer is coupled to ground, and the switching stage comprises a first transistor having a collector node, a base node and an emitter node, and a second transistor having a collector node, a base node and an emitter node, wherein the emitter nodes of the first and second transistors are coupled, the collector node of the first transistor is coupled to the output node of the voltage reducer, and the collector node of the second transistor is coupled to the first node of the primary winding of the transformer, and wherein the oscillation control stage provides a first oscillation control signal to the base node of the first transistor and a second oscillation control signal to the base node of the second transistor.

In some cases, the oscillation control stage comprises a first resistor having first and second nodes, the first node being coupled to the base node of the second transistor for providing the second oscillation control signal, and the second node being coupled to ground; a second resistor having first and second nodes, the first node of the second resistor being coupled to the collector node of the first transistor and to the output node of the voltage reducer, and the second node of the second resistor being coupled to the base node of the first transistor for providing the first oscillation control signal; and, a capacitor having first and second nodes, the first node of the first capacitor being coupled to the base node of the first transistor and the second node of the second resistor, and the second node of the first capacitor being coupled to the collector node of the second transistor and the first node of the primary winding of the transformer.

The switching frequency of the switching sequence can be approximately 50 kHz or less.

In some embodiments, the voltage reducer includes a resistive portion and a capacitive portion, and the output node of the voltage reducer is between the resistive and capacitive portions and provides the reduced voltage. The capacitive portion can provide voltage filtering.

The reduced voltage can be approximately 50 Volts.

In another aspect, at least one embodiment of the invention provides a standby circuit that generates a control signal for configuring a main power supply circuit to operate in one of a full operation mode and a standby operation mode. The standby circuit comprises a standby power supply block for producing a power supply signal based on a rectified voltage signal, the standby power supply block including a transformer with a primary winding and a secondary winding, the primary winding receiving an oscillating version of the rectified voltage signal, and the secondary winding producing the power supply signal, the standby power supply block further including an oscillation block that provides the oscillating version of the rectified voltage signal to the primary winding of the transformer, wherein the oscillation block uses the oscillation signal as feedback for adjusting the oscillation signal. The standby circuit further comprises a control block coupled to the standby power supply block to receive the power supply signal, the control block receives a mode control signal that indicates the operation mode and generates a coupling signal based on the mode indicated by the mode control signal, the control signal being based on the coupling signal.

These and other features of the embodiments described herein are provided in more detail below.

### BRIEF DESCRIPTION OF THE DRAWINGS

For a better understanding of the various embodiments described herein and to show more clearly how they may be carried into effect, reference will now be made, by way of example only, to the accompanying drawings in which:

FIG. 1 is a block diagram of an exemplary embodiment of an electronic device having a main power supply circuit and a standby circuit;

FIG. 2 is a block diagram showing an exemplary embodiment for the standby circuit of FIG. 1; and, FIG. 3 is a block diagram showing another exemplary embodiment of a standby power supply block that can be used in the standby circuit of FIG. 1.

### DETAILED DESCRIPTION

It will be appreciated that for simplicity and clarity of illustration, elements shown in the figures have not necessarily been drawn to scale with respect to one another. Further, where considered appropriate, reference numerals may be repeated among the figures to indicate corresponding or analogous elements. In addition, numerous specific details are set forth in order to provide a thorough understanding of the various exemplary embodiments. However, it will be understood by those of ordinary skill in the art that the some of the embodiments may be practiced without these specific details. In other instances, well-known methods, procedures and components have not been described in detail so as not to obscure the invention. It should further be understood that these exemplary embodiments should not be construed as limiting the scope of the invention in any way.

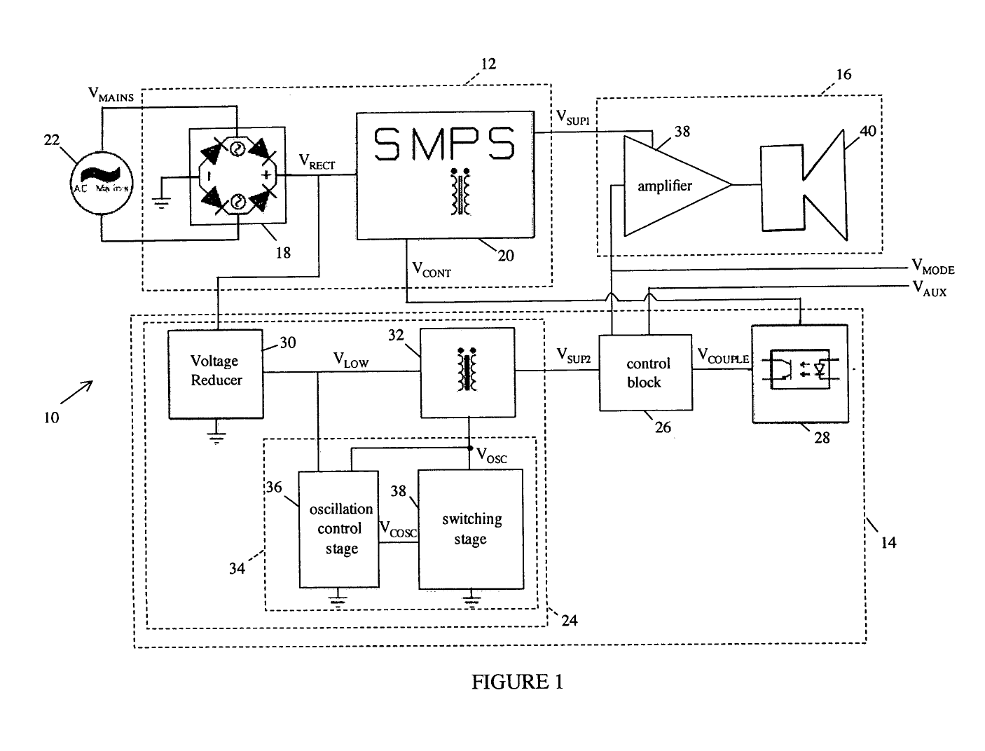

Referring first to FIG. 1, shown therein is an exemplary embodiment of an electronic device 10 having a main power supply circuit 12, a standby circuit 14 and an application circuit 16. The electronic device 10 can generally operate in a full operation mode and a standby operation mode. In the full operation mode, the main power supply circuit 12 is enabled and supplies power to the application circuit 16. In the standby operation mode, the main power supply circuit 12 is inactive and consumes negligible power (less than 0.5 W in some implementations). However, in standby mode, the standby circuit 14, which dissipates low power, waits for a mode control signal V_{MODE} to indicate that the mode of operation is to be changed to the full operation mode. The standby circuit 14 has an efficient design with a minimal number of components, which results in a reduction in power consumption and electromagnetic interference. In some implementations, the standby circuit 14 uses low voltage signals, and hence low voltage semiconductors, and a simplified transformer design, as is described in more detail below.

The mode control signal V_{MODE} can be related to an input signal that is typically received by the electronic device 10. For instance, in some embodiments, the electronic device 10 can be an audio amplifier (as is currently shown) and the mode control signal V_{MODE} can be an audio input signal that is provided to the audio amplifier for amplification. In other embodiments, the application circuit 16 of the electronic device 10 can have a different structure and function. In some cases, the mode control signal V_{MODE} can be another type of electrical signal or an optical or mechanical contact type signal.

Since, in some embodiments, the mode control signal V_{MODE} is an input signal that is normally provided to the application circuit 16, it is provided to both the application circuit 16 and the standby circuit 14. In this sense, the standby circuit 14 can automatically enable the main power supply circuit 12 to power the application circuit 16 when an input signal with useful content is provided to the electronic device 10. When the mode control signal V_{MODE} indicates that the mode of operation should change to the full operation mode, the standby circuit 14 enables the main power supply sub-circuit 12 by providing an appropriate value via a power control signal V_{CONT}. Otherwise, when the mode of operation is the standby operation mode, the standby circuit 14 disables the main power supply circuit 12 via the power control signal V_{CONT}. The power control signal V_{CONT} can be applied to the primary side of the main power supply circuit 12.

In some embodiments, the electronic device 10 may also receive an auxiliary control signal V_{AUX} as indicated in FIG. 1. The auxiliary control signal V_{AUX}, which is optional, can be provided to override the automatic enabling that is provided by the mode control signal V_{MODE}. This is beneficial for certain circumstances in which the mode control signal V_{MODE} includes a noise component and not a valid input signal component. In these situations, depending on the size of the noise component, the standby circuit 14 may incorrectly activate the main power supply circuit 12. This can be over-ridden by providing a suitable value via the auxiliary control signal V_{AUX}. For instance, the auxiliary control signal V_{AUX} may be configured by a user of the device 10 to allow automatic triggering by the mode control signal 18 or the auxiliary control signal V_{AUX} may be configured by a user of the device 10 to not allow automatic enabling by the mode control signal 18. Alternatively, in some implementations, the auxiliary control signal V_{AUX} can be directly used to enable and disable the main power supply circuit 12. For example, the auxiliary control signal V_{AUX} may be configured by an input device that is actuated by the user of the electronic device 10. The input device may be mechanical such as a switch, a button and the like or electronic such as a transistor that is controlled by other equipment. The auxiliary control signal V_{AUX} may also be configured by a protection circuit and therefore allow the electronic device 10 to turn-off in case of a failure.

In this exemplary embodiment, the main power supply circuit 12 includes a rectifier 18 and a main power supply block 20. The rectifier 18 may be a full-wave rectifier or any other suitable rectifier. The main power supply block 20 may be a switched mode power supply or any other suitable power supply.

A power source 22 provides an AC mains voltage V_{MAINS} to the main power supply circuit 12. The AC mains voltage V_{MAINS} is rectified by the rectifier 18 to produce a rectified AC mains voltage V_{RECT}. The main power supply block 20 receives the rectified mains voltage V_{RECT} and the power control signal V_{CONT}. During full operation mode, the main power supply block 20 is enabled and provides a power supply signal V_{SUP1} to power the application circuit 16. During the standby operation mode, the main power supply block 20 is disabled and does not provide the power supply signal Vₛᵤₚ₁ to the application circuit 16.

The standby circuit 14 includes a standby power supply block 24, a control block 26 and a coupling unit 28. The standby power supply block 24, the control block 26 and the coupling unit 28 are preferably made from low power consumption circuits and/or have elegant designs for reducing power consumption. In some implementations, the standby power supply block 24 can be a low power switched mode power supply. The coupling unit 28 isolates the main power supply circuit 12 from the standby circuit 14. In some implementations, the coupling unit 28 may be an opto-coupler as currently shown.

The standby power supply block 24 receives the rectified AC mains voltage V_{RECT} and provides a second supply voltage signal V_{SUP2}, which is used to power the control block 26. The control block 26 monitors the mode control signal V_{MODE} and the auxiliary control signal V_{AUX} and, based on the state of these signals, sends a coupling signal V_{COUPLE} to the coupling unit 28. If the mode control signal V_{MODE} and the auxiliary control signal V_{AUX} indicate that the mode of operation is the full operation mode, then the control block 26 interacts with the coupling unit 28 via the coupling signal V_{COUPLE} to generate the power control signal V_{CONT} so as to enable the main power supply 20. Otherwise, the control block 26 interacts with the coupling unit 28 to generate the power control signal V_{CONT} so as to not enable the main power supply block 20.

The standby power supply block 24 includes a voltage reducer 30, a transformer 32, and an oscillation block 34. The oscillation block 34 includes an oscillation control stage 36 and a switching stage 38. The transformer 32 and the oscillation block 34 are connected in parallel with the voltage reducer 30. There is also a feedback connection from the switching stage back 38 back to the oscillation control stage 36.

The voltage reducer 30 receives the rectified AC mains voltage V_{RECT} and produces a reduced voltage V_{LOW}. In some implementations, the voltage reducer 30 can also include an auxiliary rectifier and the voltage reducer 30 can be directly connected to the power source 22 to receive the voltage V_{MAINS}. The voltage reducer 30 can be a passive or an active circuit. Passive circuits that can be used for the voltage reducer 30 include resistive and/or reactive components and can be in the form of resistive or capacitive voltage dividers. Active circuits that can be used for the voltage reducer 30 can have a switching component; examples of active circuits include, but are not limited to, switched mode power supplies and phase-controlled AC switches such as thyristors.

The oscillation control stage 36 provides at least one control signal Vcosc to the switching stage 38 to turn the switching stage 36 on and off. The number of control signals that are provided to the switching stage 38 can depend on the number of switches that are in the switching stage 38. The oscillation control stage 36 can be made using passive or active components. Passive components can include resistive, and reactive components. Active components can include transistors that provide switching control signals. The oscillation control stage 36 can be implemented so that the oscillation control signal Vcosc is a constant or variable, linear or non-linear voltage or current control signal.

The switching stage 36 includes at least one switch. In some embodiments, the switching stage 36 can be a two-transistor switch. The output node of the switching stage 38 is an oscillation signal V_{OSC} that is provided to the transformer 32 to control the output voltage V_{SUP2} of the transformer 32. The switching stage 36 can be in an open or closed state. When the switching stage 36 is activated and closes, a first voltage is applied to the primary of the transformer 32 via the oscillation signal V_{OSC}. When the switching stage 36 is open, a second voltage is applied to the primary of the transformer 32. The frequency and duty cycle of the switching stage 38 switches the voltage across the primary of the transformer 32 and hence the output voltage of the transformer 32. The frequency and duty cycle of the switching stage 38 depends on the configuration of the oscillation control stage 36, the values of the components used in the oscillation control stage 36, the parameters of the switching components, the parameters of the transformer 32 and the topology of the standby power supply block 24.

The transformer 32 also provides isolation between the standby power supply block 24 and the remainder of the standby circuit 14. Due to very low output power required to power the control block 28 and the use of the voltage reducer 30, feedback from the transformer 32, an auxiliary supply or voltage clamping windings do not have to be used. The use of the voltage reducer 30 also makes the design less sensitive to the effects of the leakage inductance in terms of peak voltages, output voltage regulation and switching power losses. In some implementations, the transformer 32 can have a simplified design with one primary winding and one secondary winding. Also, in some implementations, a small UU core with sectional bobbin can be used for the transformer 32, which reduces the cost and allows the design to meet EMI and safety requirements. The output voltage V_{SUP2} of the transformer 32 is used to supply power to the components of the control block 26. The output voltage V_{SUP2} depends on the voltage signal V_{LOW}, the frequency and duty cycle for which the switching stage 38 is in the opened and closed stages, the characteristics of the primary and secondary windings such as the number of turns used and the coupling, and the components that are on the secondary side of the transformer 32.

Component values can be chosen for the oscillation control stage 36, the switching stage 38, and the transformer 32 so that the standby power supply block 24 acts as a low-power switched mode power supply. In some implementations, the structure of the control block 26 and the way in which the control block 26 is connected to the transformer 32 can be selected so that the standby power supply block 24 acts as a forward or flyback switched mode power supply. Further, these blocks can be configured, and the values of components in these blocks can be selected, so that the standby power supply block 24 operates in a discontinuous, critically discontinuous or continuous mode which all refer to the current through the whole transformer 32. Discontinuous mode is advantageous because of low power requirements, which allows for smaller transformer size, lower turn-ON switching losses and improved EMI.

The application circuit 16 can be any electronic circuit that requires supply power. In some embodiments, the application circuit 16 is an audio amplifier and includes an amplification circuit 40 and a speaker 42. Accordingly, in these embodiments, an input audio signal can be provided as the mode control signal V_{MODE} and the presence of audio triggers the control block 26 to enable the main power supply circuit 12. When the main power supply circuit 12 is enabled, power is supplied to the amplification circuit 40 which also receives the input audio signal and produces an amplified audio signal that is output by the speaker 42. When there is no audio signal, the main power supply circuit 12 is put into standby operation mode so that it does not consume any power.

The voltage reducer 30 allows low voltage components to be used in the oscillation block 34, and a simplified design for the transformer 32. For instance, the coupling requirement for the transformer 32 can be reduced which results in lower EMI, and eases the safety requirements for the standby power supply block 24. In conventional switched mode power supplies, higher voltages are used which requires the use of higher voltage components, and more complex control schemes and designs for the transformer.

Furthermore, the voltage reducer 30, and the low power requirements allow lower switching frequencies to be used without increasing the size of the transformer 32. For example, switching frequencies of approximately 50 kHz or less can be used. This is advantageous since the third harmonic will be at or lower than the 150 kHz limit for Electromagnetic Interference (EMI). In addition, feedback is provided from the switching stage 38 to the oscillation control stage 36 rather than relying on feedback from the transformer 32. In conventional switched mode power supplies, the transformer has additional windings to provide feedback for oscillation which results in a more complicated design.

The voltage reducer 30 also allows for a reduction in circuit complexity for other components in the standby power supply block 24. For instance, the voltages V_{LOW}and V_{OSC} can be directly connected to the oscillation block 34. All of these simplifications allow the design for the standby power supply block 24 to be very compact.

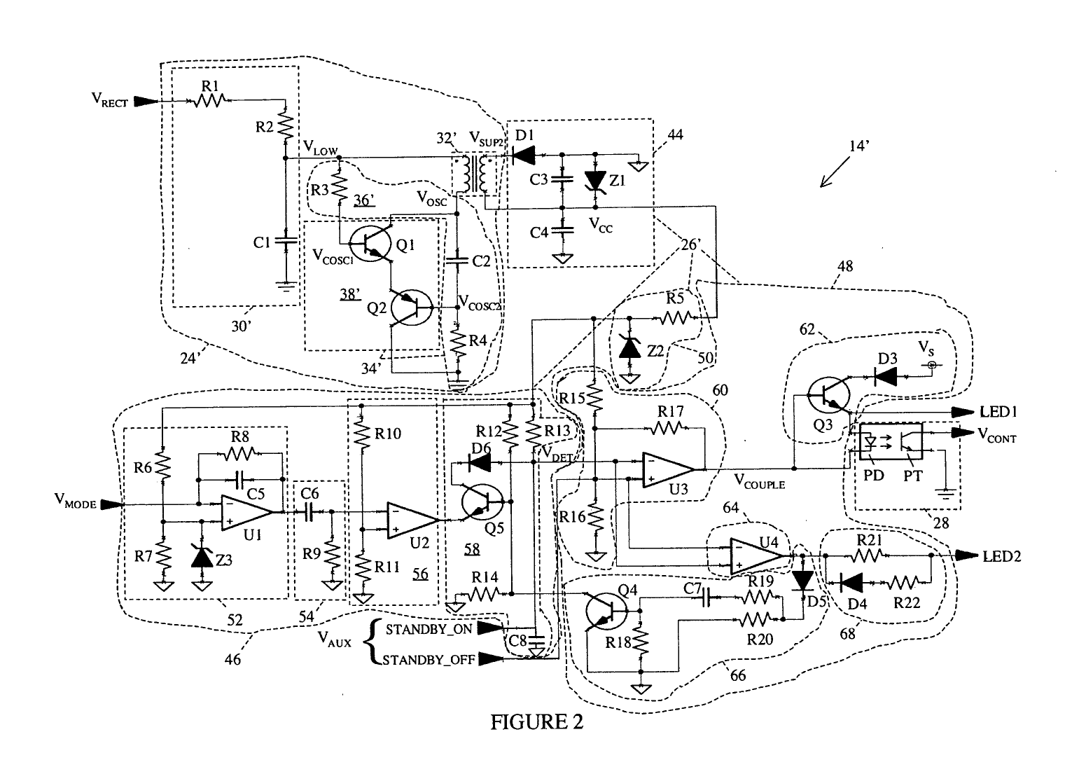

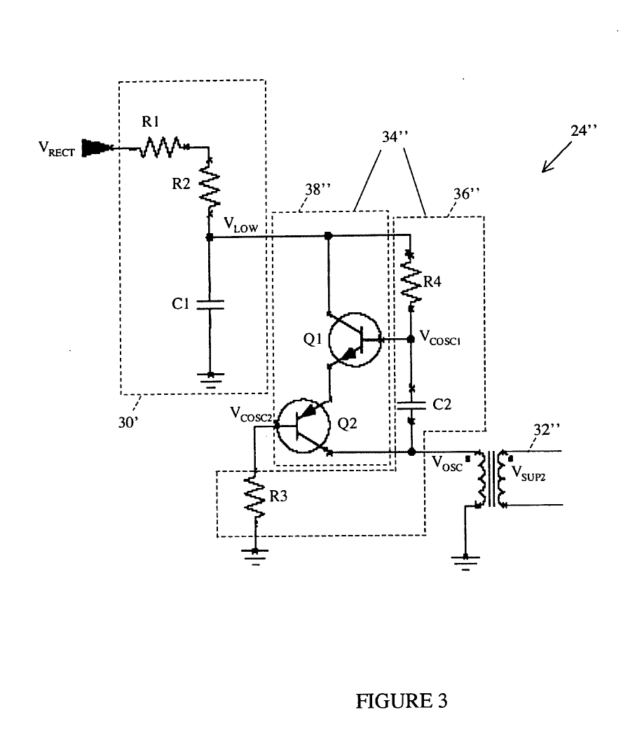

Referring now to FIG. 2, shown therein is an exemplary embodiment 14′ for the standby circuit of FIG. 1. A list of exemplary values for the components shown in FIG. 2 is provided in Table 1. The standby circuit 14′ includes a standby power supply block 24′, a control block 26′ and the coupling unit 28′. The standby power supply block 24′ includes a voltage reducer 30, a transformer 32′, and an oscillation control block 34′ having an oscillation control stage 34′ and a switching stage 38′. In this exemplary implementation, the standby power supply block 24′ has a flyback topology. The control block 26 includes a regulator 44, a detection circuit 46 and a control circuit 48.

The voltage reducer 30′ can be a resistor-capacitor circuit with a resistive portion that includes resistors R1 and R2 connected in series and a capacitive portion that includes a capacitor C1. A first node of the resistor R1 is connected to the rectified AC mains voltage V_{RECT} and a second node of the resistor R1 is connected to a first node the resistor R2. A second node of the resistor R2 is then connected to a first node of the capacitor C1. The second node of the capacitor C1 is connected to ground. The output voltage V_{LOW} is taken from the node between the resistor R2 and the capacitor C1. The values of the resistors R1 and R2 are selected to provide a sufficient reduction in the magnitude of the voltage V_{RECT} to allow low voltage components to be used in the standby circuit 24′. In some implementations, these parameters are selected to obtain a voltage reduction of about ⅓, which results in a maximum voltage of about 50 Volts. The use of the capacitor C1 in the voltage reducer 30′ provides some filtering to smooth the output voltage V_{LOW}.

In some implementations, the voltage reducer 30′ can include an auxiliary rectifier that can be connected in series with the resistors R1 and R2 to provide a reduced rectified voltage to the capacitor C1. In this case, the resistors R1 and R2 are connected to a power source to receive the voltage V_{MAINS}. In other implementations, instead of using the resistors R1 and R2, a capacitor can be used to reduce power consumption (i.e. the power dissipation of resistors R1 and R2).

The oscillation control stage 36′ includes two resistors R3 and R4 and a capacitor C2. The switching stage 38′ includes an npn bipolar junction transistor Q1 and a pnp bipolar junction transistor Q2 connected in series such that the emitter of transistor Q1 is connected to the emitter of transistor Q2. The two transistors Q1 and Q2 can be low voltage transistors because of the voltage reduction provided by the voltage reducer 30′. The two transistors Q1 and Q2 receive two control signals V_{COSC1} and V_{COSC2} but act as a single switch to modulate the voltage across the primary of the transformer 32′. The voltage differential between the control signals V_{COSC1} and V_{COSC2} determine whether the transistors Q1 and Q2 are on or off. For both transistors Q1 and Q2 to be conducting, feedback is used by the oscillation control stage 36′ as described below. The use of the two transistors Q1 and Q2 allows the oscillation control stage 36′ to have a more simplified design and also avoids the use of extra windings on the transformer 32′.

A first node of resistor R3 is connected to the output node of the voltage reducer 30′ and a first node of the primary winding of the transformer 32′. A second node of the resistor R3 is connected to the base mode of the transistor Q1 to bias the transistor Q1. The collector node of the transistor QI is connected to a second node of the primary winding of the transformer 32′. Accordingly, the voltage V_{LOW} is provided to the transformer 32′ and a switched version of the voltage V_{LOW} is provided to the switching stage 38′, depending on whether the switching stage 38′ is ON (i.e. conducting) or OFF (i.e. not conducting). A first node of the capacitor C2 is connected to both the collector node of the transistor Q1 and the second node of the primary winding of the transformer 32′. A second node of the capacitor C2 is connected to the base node of the transistor Q2. A first node of the resistor R4 is connected to the base node of the transistor Q2 and the second mode of the capacitor C2. A second node of the resistor R4 is also connected to collector node of the transistor Q2 and to ground.

At the beginning of a switching cycle, both of the transistors Q1 and Q2 are off. The voltage V_{LOW} is at the first node of the primary winding of the transformer 32′. The capacitor C2 is charged and at first appears as an open circuit. Accordingly, the voltage V_{LOW} is at the second node on the primary winding of the transformer 32′. Current then begins to flow through the resistor R3, from the base node to the emitter node of the transistor Q1, from the emitter node to the base node of the transistor Q2, and the resistor R4. This causes the transistors Q1 and Q2 to turn on. When both of the transistors Q1 and Q2 turn on, they appear as small resistors and provide a low resistance path to ground. The capacitor C2 then begins to discharge along the path defined from the collector node to the emitter node of transistor Q1, the emitter node to the collector node of transistor Q2 to ground and then through the resistor R4. The capacitor C2 also discharges through the path defined from the collector node to the emitter node of transistor Q1, and the emitter node to the base node of transistor Q2.

As the current through the transistors Q1 and Q2 increases and the capacitor C2 discharges, a threshold point is reached at which point the transistors Q1 and Q2 are no longer in saturation. The voltage (i.e. V_{OSC}) across the transistors Q1 and Q2 rises, the capacitor C2 starts to charge through the resistor R4, which increases the control voltage V_{COSC2} which in turns causes transistors Q1 and Q2 to turn off. During this turn-off transition, the portion of the oscillation control stage 36′ defined by the capacitor C2 and the resistor R4 provides positive feedback in order to more quickly turn off the switching stage 38′. When both transistors Q1 and Q2 turn off, the capacitor C2 charges to V_{LOW} plus the voltage across the primary winding of the transformer 32′. As the capacitor C2 charges, the control voltage V_{COSC2} starts to drop. When the control voltage V_{COSC2} becomes lower than a certain turn-on threshold voltage, current starts to flow through the resistor R3, from the base node to the emitter node of the transistor Q1, from the emitter node to the base node of the transistor Q2 and the resistor R4. The voltage V_{OSC} then starts to drop and the cycle repeats. The rate at which the capacitor C2 charges and discharges is dictated by the RC time constant determined by the capacitor C2, the resistor R4 as well as the parameters of the transistors Q1 and Q2. The switch timing or switching sequence defined by the turn-ON and turn-OFF times of the transistors Q1 and Q2, can be adjusted by varying the values of the components C2, R3 and R4 so that the standby circuit 24′ operates in discontinuous, critically discontinuous or continuous mode for a specific load.

As the switching stage 38′ is turning on and off, and the capacitor C2 is charging and discharging, the voltage across the primary winding of the transformer 32′ is being switched. This switching voltage is then transferred to the secondary winding of the transformer 32′ and is provided as V_{SUP2} to power the control block 26′. Accordingly, the voltage V_{SUP2} is provided to the control block 26′ during both the ON and OFF periods of the switching sequence of the switching stage 38′.

The regulator 44 receives the AC signal V_{SUP2} and produces a constant voltage V_{cc}, which powers the signal detection circuit 46 and the control circuit 48. In this exemplary embodiment, the regulator 44 includes a diode D1, capacitors C3 and C4, and a zener diode Z1. A first node of the diode D1 is connected to a first node of secondary winding of the transformer 32′. A second node of the diode D1 is connected to a first node of the capacitor C3, a first node of the zener diode Z1 and to a secondary ground. The second node of the capacitor C3 and the second node of the zener diode Z1 are connected to a first node of the capacitor C4 and to a second node of the secondary winding of the transformer 32′. The second node of the capacitor C4 is connected to secondary ground. The output V_{cc} of the regulator 44 is taken from the node between the capacitors C3 and C4.

The diode D1 acts as a reverse-biased, half-wave rectifier to produce a half-wave rectified signal that is smoothed out by the capacitors C3 and C4. The smoothed out signal is clamped by the zener diode Z1 to produce a regulated voltage V_{cc} that is similar to the breakdown voltage of the zener diode Z1. The regulated voltage V_{cc} is fed to the signal detection circuit 46 and the control circuit 48 to power these circuits.

The control block 26′ includes a voltage conversion stage 50 that can be used to further modify the regulated voltage V_{cc} to provide a voltage reference V_{REF}. The voltage reference V_{REF} is used by various components in the signal detection circuit 46 and the control circuit 48 for performing comparisons and the like. In this exemplary embodiment, the voltage conversion stage includes a resistor R5, and a zener diode Z2. A first node of the resistor R5 is connected to the output node of the regulator 44. The second node of the resistor R5 is connected to the cathode of the zener diode Z2. The anode of the zener diode Z2 is connected to the secondary ground. The voltage V_{REF} is taken from the cathode of the zener diode Z2. Accordingly, the voltage V_{REF} is set to the breakdown voltage of the zener diode Z2.

The signal detection circuit 46 monitors the mode control signal V_{MODE} to determine if the standby circuit 14′ should enable the main power supply circuit 12. In some implementations, the mode control signal V_{MODE} can be an input audio signal and when the signal detection circuit 46 detects that the input audio signal reaches a specified minimum voltage, then the signal detection circuit 46 indicates this detection via detection signal V_{DET}. The control circuit 48 receives the detection signal V_{DET} and based on the information in this signal, enables or disables the main power supply block 20 via the signal V_{CONT}.

In this exemplary embodiment, the signal detection circuit 46 includes an amplification stage 52, a filtering stage 54, a comparator stage 56 and an output stage 58. Structures which are suitable for these stages include circuit topologies with components such that the stages dissipate low power and can accommodate signals having the frequency and amplitude characteristics of the mode control signal V_{MODE}.

The amplification stage 52 can be any suitable amplifier that receives the mode control signal V_{MODE} and amplifies this signal. In this exemplary implementation, the amplification stage 52 includes resistors R6, R7 and R8, zener diode Z3, capacitor Cs and operational amplifier Ul. Resistors R6 and R7 act as a voltage divider to center the output node of the operational amplifier U1 about a voltage that is in between the reference voltage V_{REF} and secondary ground. A first node of resistor R6 is connected to the reference voltage V_{REF} and a second node of the resistor R6 is connected to a first node of the resistor R7 and to the non-inverting input node of the operation amplifier U1. The second node of the resistor R7 is connected to secondary ground. The cathode of the zener diode Z3 is connected to the non-inverting input node of the operational amplifier U1. The anode of the zener diode Z3 is connected to secondary ground. Resistor R8 and capacitor CS are connected in parallel across the output node and the inverting input node of the operational amplifier U1. The mode control signal V_{MODE} is connected to the inverting input node of the operational amplifier U1. The mode control signal V_{MODE} is amplified to an appropriate level for further processing by the other components of the signal detection circuit 46.

The amplified signal is then filtered by the filtering stage 54 which is any suitable high-pass filter with a low cutoff frequency for removing any DC and very low frequency components in the amplified signal. In this exemplary implementation, the filtering stage 54 includes a capacitor C6 and a resistor R9 in a high-pass configuration. A first node of the capacitor C6 is connected to the output node of the operational amplifier U1, and a second node of the capacitor C6 is connected to a first node of the resistor R9. The other node of the resistor R9 is connected to secondary ground.

In the comparator stage 56, the filtered signal is compared with a first comparison voltage to determine if the filtered signal includes noise or a signal component. This determination is reflected in the output signal of the comparator stage 56 that is provided to the output stage 58. In this exemplary implementation, the comparator stage 56 includes two resistors RIO and R1 and an operational amplifier U2. A first node of the resistor R10 is connected to the reference voltage signal V_{REF} and a second node of the resistor RIO is connected to a first node of the resistor R1 and to the non-inverting input node of the operational amplifier U2. A second node of the resistor R1 is connected to secondary ground. The output node of the filtering stage 54 is connected to the inverting input node of the operational amplifier U2 for comparison with the first comparison voltage. The first comparison voltage is determined by the reference voltage V_{REF} and the voltage divider provided by the resistors R10 and R11. When the amplitude of the filtered signal is greater than the first comparison voltage, then the output of the operational amplifier U2 is pulled down to the negative supply voltage of the operational amplifier U2, which in this implementation is secondary ground. When the amplitude of the filtered signal is less than the first comparison voltage, then the output of the operational amplifier U2 is pulled up to the positive supply voltage of the operational amplifier U2, which is V_{cc}.

The output stage 58 includes resistors R12, R13 and R14, a capacitor C8, a transistor Q5 and a diode D6. A first node of the resistor R12 is connected to the reference voltage V_{REF}, and a second node of the resistor R12 is connected to both the base node of the transistor Q5 and a first node of the resistor R14. A second node of the resistor R14 is connected to secondary ground. The two resistors R12 and R14 act as a voltage divider to provide a constant voltage to the base node of the transistor Q5 that is a fraction of the reference voltage V_{REF}. A first node of the resistor R13 is connected to the reference voltage V_{REF}, and a second node of the resistor R13 is connected to the anode of the diode D6 and the first node of the capacitor C8. A second node of the capacitor C8 is connected to secondary ground. The second node of the resistor R13 provides the output signal V_{DET} of the signal detection circuit 46. The cathode of the diode D6 is connected to the collector node of the transistor Q5. The emitter node of the transistor Q5 is connected to the output node of the operational amplifier U2 (i.e. the output of the comparator stage 56). The transistor Q5 acts as a switch and the diode D6 ensures low leakage current to the STANDBY_ON control signal.

If the mode control signal V_{MODE} includes a signal indicating that the mode of operation should be full operation mode, then the output of the comparator stage 56 will be pulled to ground. The emitter node of the transistor Q5 will be at a lower voltage than the base node of the transistor Q5 such that the transistor Q5 will turn on. This will then pull the output voltage V_{DET} of the output stage 58 to a low voltage determined by the diode D6, the saturation voltage of the transistor Q5 and the output-low voltage of the operational amplifier U2. Otherwise, if the mode control signal V_{MODE} does not include a signal indicating that the mode of operation should be full operation mode, then the output of the comparator stage 56 will be V_{cc}. The transistor Q5 will be off and the current flowing through the resistor R13 will start to charge the capacitor C8. The output V_{DET} of the output stage 58 will then be linearly rising to the reference voltage V_{REF}. In audio circuits there are inherit pauses in audio signals. Accordingly, when the mode control signal V_{MODE} is an audio signal, the capacitor C8 provides a delay for switching into the standby mode of operation; i.e. the configuration of the output stage 58 along with the capacitor C8 ensures that short pauses in the audio signal used for the mode control signal V_{MODE} will not cause the main power supply circuit 12 to switch to the standby mode of operation. Accordingly, the portion of the circuit including the capacitor C8 determines the timing for applying the coupling signal V_{COUPLE} and hence the control signal V_{CONT}.

The control circuit 48 includes two paths with the first path having a first comparator stage 60 and a first output stage 62 and the second path having a second comparator stage 64, a feedback stage 66 and a second output stage 68. The comparator stages 60 and 64 work in a complementary manner to one another. The first comparator stage 60 and the first output stage 62 drive the coupling unit 28 to provide the V_{CONT} signal to the main power supply circuit 12. The second comparator stage 64 and the feedback stage 66 provide feedback to prevent the switch Q5 in the output stage 58 of the signal detection circuit 46 from turning back on in certain conditions. This feedback loop is required to ensure turn-off when the main power supply circuit 12 is turning off to a standby operation mode.

The first comparator stage 60 includes resistors R15, R16 and R18, and operational amplifier U3. A first node of the resistor R15 is connected to the reference voltage V_{REF}, and a second node of the resistor R15 is connected to a first node of the resistor R16 and to the non-inverting input node of the operational amplifier U3. A second node of the resistor R16 is connected to secondary ground. The resistor R18 is connected between the output node and positive input node of the operational amplifier U3 and provides positive feedback and hysteresis. The inverting input node of the operational amplifier U3 is connected to the output node of the signal detection circuit 46 to receive the voltage V_{DET}.

The first comparator stage 60 compares V_{DET} to a second comparison voltage. The second comparison voltage is determined by the reference voltage V_{REF}, and the voltage divider provided by the resistors R15 and R16. When the detection signal V_{DET} is greater than the second omparison voltage, the output of the operational amplifier U3 goes to the egative supply voltage, which in this case is secondary ground. When the etection signal V_{DET} is lower than the second comparison voltage, the output of the operational amplifier U3 goes to the positive supply voltage, which in this case is V_{cc}.

The output stage 62 includes a transistor Q3, and a diode D3. The anode of the diode D3 is connected to a supply voltage Vₛ and the cathode of the diode D3 is connected to the collector of the transistor Q3. In some implementations, the supply voltage Vₛ is 15 V and is supplied by the main power supply circuit when it is operating in full operation mode. The base node of the transistor Q3 is connected to the output node of the operational amplifier U3. The emitter node of the transistor Q3 is connected to a first input node of the coupling unit 28 and the output node of the operational amplifier U3 is connected to a second input node of the coupling unit 28. The transistor Q3 is used as a switch and the diode D3 biases the transistor Q3 so that it acts as a true switch. As indicated, an optional LED can be connected to the emitter of the transistor Q3 to receive the LED signal LED1 to show when the electronic device is operating in stand-by mode.

With regards to the coupling unit 28, in some implementations the coupling unit 28 is an opto-coupler that, for simplifying the description, includes a photo-diode PD and a photo-transistor PT. A first node of the photo-transistor PT is connected to a first output node of the coupling unit 28 and provides the control signal V_{CONT}. A second node of the photo-transistor PT is connected to a second output node of the coupling unit 28 and is connected to ground. The first input node of the coupling unit 28 is connected to the anode of the photo-diode PD and the second input node of the coupling unit 28 is connected to the cathode of the photo-diode PD.

When the mode control signal V_{MODE} indicates that the mode of operation should be full operation mode, the output of the operational amplifier U3 will be high (i.e. at the potential of V_{cc}). The transistor Q3 will be on and there will be a reversed differential voltage across the photo-diode PD. In this case, light is not produced by the photo-diode PD and the output of the photo-transistor PT is open, and hence the control signal V_{CONT} will be high. The main power supply block 20 includes structure such that it is enabled when the signal V_{CONT} is high.

When the mode control signal V_{MODE} indicates that the mode of operation should be standby operation mode, the output of the operational amplifier U3 will be low (i.e. at the secondary ground). The transistor Q3 will be off and the photo-diode PD will be on. In this case, light is produced by the photo-diode PD and the output of the photo-transistor PT, and the signal V_{CONT}, will be low. The main power supply block 20 will be disabled when the signal V_{CONT} is low.

The transistor Q3 is connected to the voltage Vₛ through the diode D3. Using an external voltage supply allows the brightness of an LED connected to signal LED1 to be increased during the full operation mode without increasing the power consumption of the standby circuit 14′. The LED that is used can be a bicolor LED and can be connected between the nodes providing the signals LED1 and LED2 to indicate when the electronic device 10 is operating in full operation mode and standby operation mode. The LED2 signal is also used to supply power to the coupling unit 28 when the signal V_{COUPLE} is low. The signal LED1 can be referred to as a first indication signal and the signal LED2 can be referred to as a second indication signal.

The LED1 and LED2 signals are not limited for use only in LED applications. The LED1 and LED2 signals can also be used to control external electronic circuits. For example, the LED1 and LED2 signals can be used also to mute the amplifier 38 during ON/OFF transitions, control the sleep/wake-up transitions for a microcontroller, control a 12V trigger output (a 12V trigger output is common in Hi-Fi audio systems), and the like.

The second comparator stage 64 includes an operational amplifier U4 and uses the second comparison voltage provided by the voltage divider formed by the resistors R15 and R16, and the detection signal V_{DET}. The second comparison voltage is connected to the inverting input node of the operational amplifier U4 and the detection signal V_{DET} is connected to the non-inverting input node of the operational amplifier U4. Accordingly, when the signal V_{DET} is low, which indicates that the mode control signal V_{MODE} is signifying that the mode of operation should be full operation mode, the output of the operational amplifier U4 will go to the negative supply voltage which in this case is secondary ground. When the signal V_{DET} is high, which indicates that the mode control signal V_{MODE} is signifying that the mode of operation should be standby operation mode, the output of the operational amplifier U4 will go to the positive supply voltage, which in this case is V_{cc}. Accordingly, the second comparator stage 64 produces the opposite result that is produced by the first comparator stage 60.

The feedback stage 66 includes resistors R18, R19 and R20, capacitor C7, diode D5, and transistor Q4. The anode of the diode D5 is connected to the output node of the operational amplifier U4, and the cathode of the diode D5 is connected to a first node of both the resistor R19 and the resistor R20. A second node of the resistor R20 is connected to secondary ground. A second node of the resistor R19 is connected to a first node of the capacitor C7. A second node of the capacitor C7 is connected to the base node of the transistor Q4 and a first node of the resistor R18. A second node of the resistor R18 is connected to secondary ground. The emitter node of the transistor Q4 is also connected to secondary ground, and the collector node of the transistor Q4 is connected to the base node of the transistor Q5 of the output stage 58 of the signal detection circuit 46.

When the output of the second comparator stage 64 is V_{cc}, this signifies that V_{DET} is greater than the reference voltage V_{REF} which means that the mode control signal V_{MODE} indicates that the mode of operation should be the standby mode. In this case, when the feedback stage 66 activates, the output voltage of the operational amplifier U4 charges the capacitor C7 supplying a current to the base node of the transistor Q4 to turn on the transistor Q4. When the transistor Q4 turns on, it pulls the base node of the transistor Q5 to secondary ground which ensures that the transistor Q5 remains off. This ensures that there is no false switching between modes when there is some noise in the mode control signal V_{MODE}. The noise can be voltage transients caused by the turning-off of the main power supply circuit 12. The resistor R19 and the capacitor C7 provide a time constant for the pulse generated at the output of the transistor Q4. The resistor R20 provides a discharge path for the capacitor C7.

The output stage 68 includes resistors R21 and R22, and diode D4. The cathode of the diode D4 is connected to the output node of the operational amplifier U4 and the anode of the diode D4 is connected to a first node of the resistor R22. The second node of the resistor R22 is connected to a first node of the resistor R21. The second node of the resistor R21 is connected to the cathode of the diode D4 and the output node of the operational amplifier U4. As indicated, an optional LED can be connected to the first node of the resistor R21. The resistors R21, and R22 and the diode D4 are used to control the intensity of the signal LED2 during both the full operation and standby modes of the electronic device 10. The diode D4 also reduces the power consumption of the standby circuit 14′ during standby operation mode (i.e. the output of the amplifier U4 is high, which in this exemplary case is V_{cc}). The use of a bicolor LED allows the output stage 68 to be connected to the coupling unit 28 to provide supply power to the coupling unit 28 when the signal V_{COUPLE} is low. If a bicolor LED is not used, then another suitable electronic component can be used to connected the LED2 signal to the coupling unit 28 to provide supply power when needed. For instance, a diode can be connected between the LED2 and LED1 signal outputs to provide the required power for the coupling unit 28 if a bicolor LED is not used. In this case, the cathode of the diode is connected at the node marked LED1.

The control circuit 48 can also include two additional external auxiliary inputs STANDBY_ON and STANDBY_OFF. The STANDBY_ON signal is connected to the output node of the signal detection circuit 46. The STANDBY_OFF signal is connected to the non-inverting input node of the operational amplifier U3 in the first comparator stage 60. These two external control signals can be used to override the automatic operation of the standby circuit 14′ to turn the main power supply block 20 on or off. When the STANDBY_ON signal is set to ground, this provides the same effect as when the signal V_{DET} is low and which ultimately enables the main power supply circuit 12 to operate in the full operation mode. When the STANDBY_OFF signal is set to ground, this provides the same effect when the signal V_{DET} is high and ultimately enables the main power supply circuit 12 to operate in the standby operation mode. Further, when the V_{DET} signal is low due to the presence of a valid input signal component in the mode control signal V_{MODE}, the signal V_{DET} is approximately 1V. If the STANDBY_OFF signal is brought to a lower level than the V_{DET} signal, then the electronic device 10 can be placed into standby operation mode. The auxiliary input STANDBY_OFF can override the delay associated with the capacitor C8.

TABLE 1
EXEMPLARY VALUES FOR COMPONENTS IN FIG. 2

| REF. Label | Component Type | Details |
|---|---|---|
| C1 | Capacitor | .01UF 100 V 10% |
| C2 | Capacitor | 470PF 100 V 5% |
| C3 | Capacitor | 100PF 100 V 5% |
| C4 | Capacitor | 1UF 50 V 10% |
| C5 | Capacitor | 100PF 50 V 5% |
| C6 | Capacitor | .1UF 50 V 5% |
| D1 | Diode | BAS16 |
| D3 | Diode | BAS16 |
| D4 | Diode | BAS16 |
| D5 | Diode | BAS16 |
| D6 | Diode | BAS16 |
| Q1 | Transistor | MMBT5551 |
| Q2 | Transistor | MMBT5401 |
| Q3 | Transistor | MMBT4401 |
| Q4 | Transistor | MMBT4401 |
| Q5 | Transistor | MMTB4401 |
| R01 | Resistor | 100K ¼ W 1% |
| R02 | Resistor | 475K ¼ W 1% |
| R03 | Resistor | 1M00 ⅛ W 1% |
| R04 | Resistor | 1M00 ⅛ W 1% |
| R05 | Resistor | 10K0 ⅛ W 1% |
| R06 | Resistor | 499K ⅛ W 1% |
| R07 | Resistor | 499K ⅛ W 1% |
| R08 | Resistor | 499K ⅛ W 1% |
| R09 | Resistor | 100K ⅛ W 1% |
| R10 | Resistor | 499K ⅛ W 1% |
| R11 | Resistor | 1K00 ⅛ W 1% |
| R12 | Resistor | 255K ⅛ W 1% |
| R13 | Resistor | 2M21 ⅛ W 1% |
| R14 | Resistor | 499K ⅛ W 1% |
| R15 | Resistor | 220K ⅛ W 5% |
| R16 | Resistor | 499K ⅛ W 1% |
| R17 | Resistor | 4M7 ⅛ W 5% |
| R18 | Resistor | 100K ⅛ W 1% |
| R19 | Resistor | 255K ⅛ W 1% |
| R20 | Resistor | 499K ⅛ W 1% |
| R21 | Resistor | 4.02K ⅛ W 1% |
| R22 | Resistor | 1K ⅛ W 1% |
| Z1 | Zener Diode | MMBZ5237 8.2 V |
| Z2 | Zener Diode | MMBZ5234 6.2 V |
| Z3 | Zener Diode | MMBZ228 3.9 V |
| 32 | Transformer | 8 mH |

Referring now to FIG. 3, shown therein is a block diagram of another exemplary embodiment of a standby power supply block 24″ that can be used in the standby circuit 14. The standby power supply block 24″ includes the voltage reducer 30′, a transformer 32″, and an oscillation block 34″ having an oscillation control stage 36″ and a switching stage 38″. The switching stage 38″ includes the two transistors Q1 and Q2 connected such that the collector node of the transistor Q1 is connected to the output node of the voltage reducer 30′ (i.e. the node between the resistor R2 and the capacitor C1). The emitter node of the transistor Q1 is connected to the emitter node of the transistor Q2. The oscillation control stage 36″ includes resistors R3 and R4 and capacitor C2. A first node of the resistor R3 is connected to the base node of the transistor Q2 and a second node of the resistor R3 is connected to ground. A first node of the resistor R4 is connected to the collector node of the transistor Q1 and the output node of the voltage reducer 30′. A second node of the resistor R4 is connected to the base node of the transistor Q1. A first node of the capacitor C2 is connected to the second node of the resistor R4 and the base node of the transistor Q1. A second node of the capacitor C2 is connected to the collector node of the transistor Q2 and to a first node of the primary winding of the transformer 32″. A second node of the primary winding of the transformer 32″ is connected to ground.

The oscillation block 24″ operates in a similar fashion as the oscillation block 24′ since the switching arrangement, i.e. components R3, R4, C2, Q1 and Q2, have not changed. Rather, the topology of the switching arrangement of the oscillation block 24′ is a somewhat mirrored version of the switching arrangement of the oscillation block 24′. Accordingly, the operation of the standby power supply block 24 does not need to be discussed. Further, the component values for the standby power supply block 24″ are similar to those given in Table 1.

With respect to the standby power supply block 24′, it is to be noted that the second node of the resistor R3 can be connected to a different reference voltage potential. However, this node can only be connected to a “high” reference voltage potential during the OFF state of the switching stage 38′. The same is generally true for the standby power supply block 24″ taking into account the mirrored configuration and so the “high” reference voltage becomes low and so on and so forth.

Further, with respect to both standby power supply blocks 24′, and 24″, the signal V_{cosc1} can be variable, for example it can be linearly changing. In addition, the signal Vcosci can be provided by an RC circuit or another type of suitable circuit. Further, reversing the polarity of the power supply (i.e. the voltage V_{LOW} becomes negative referenced to ground) will require implementing the transistor Q1 with a pnp transistor and transistor Q2 with an npn transistor.

With regards to both oscillation blocks 34′ and 34″, it is to be noted that transistors Q1 and Q2 are not limited to bipolar transistors. Further, in some implementations a single 4 pin integrated switching device can be used that provides the functionality of transistors Q1 and Q2.

It should be understood that various modifications can be made to the embodiments described and illustrated herein without departing from the invention, the scope of which is defined in the appended claims.

1. An electronic device comprising:
a) an application circuit;
b) a main power supply circuit coupled to a power source and the application circuit, the main power supply circuit operates in a full operation mode and a standby operation mode, wherein during the full operation mode the main power supply circuit provides a first power supply signal to the application circuit and during the standby mode the main power supply does not provide the first power supply signal to the application circuit; and, c) a standby circuit coupled to the main power supply circuit,
the standby circuit provides a control signal to the main power supply circuit to configure the main power supply to operate in one of the full operation mode and the standby operation mode.

2. The electronic device of claim 1, wherein the standby circuit comprises:
d) a standby power supply block that provides a second power supply signal;
e) a control block coupled to the standby power supply block to receive the second power supply signal, the control block receives a mode control signal that indicates the operation mode and generates a coupling signal based on the mode control signal and determines timing for applying the coupling signal; and,
f) a coupling unit coupled to the control block and the main power supply block, the coupling unit generates the control signal based on the coupling signal.

3. The electronic device of claim 2, wherein the control block also receives an auxiliary control signal and is adapted to override the mode control signal and generate the coupling signal based on the auxiliary control signal.

4. The electronic device of claim 2, wherein the standby power supply block omprises:
g) a voltage reducer that receives a rectified version of an AC mains voltage and produces a reduced voltage;
h) a transformer having a primary winding and a secondary winding, the primary winding having first and second nodes, the primary winding receiving a switched version of the reduced voltage, and the secondary winding being coupled to the control block to provide the second power supply signal;
i) a switching stage coupled to the primary winding of the transformer for providing an oscillation signal to the primary winding of the transformer; and,
j) an oscillation control stage coupled to the voltage reducer and the switching stage, the oscillation control stage receives the reduced voltage and produces at least one oscillation control signal to control the switching of the switching stage, wherein the switching stage provides the oscillation signal as feedback to the oscillation control stage for altering the at least one oscillation control signal.

5. The electronic device of claim 4, wherein the first node of the primary winding of the transformer is coupled to the voltage reducer and wherein the switching stage comprises a first transistor having a collector node, a base node and an emitter node, and a second transistor having a collector node, a base node and an emitter node, wherein the emitter nodes of the first and second transistors are coupled, the collector node of the first transistor is coupled to the second node of the primary winding of the transformer, and the collector node of the second transistor is coupled to the oscillation control stage and to ground, and wherein the oscillation control stage provides a first oscillation control signal to the base node of the first transistor and a second oscillation control signal to the base node of the second transistor.

6. The electronic device of claim 5, wherein the oscillation control stage comprises:
k) a first resistor having first and second nodes, the first node being coupled to the output node of the voltage reducer to receive the reduced voltage and the second node being coupled to the base node of the first transistor for providing the first oscillation control signal;
l) a capacitor having first and second nodes, the first node of the capacitor being coupled to the collector node of the first transistor and the second node of the capacitor being coupled to the base node of the second transistor; and,
m) a second resistor having first and second nodes, the first node of the second resistor being coupled to the second node of the capacitor and to the base node of the second transistor to provide the second oscillation control signal, and the second node of the second resistor being coupled to the collector node of the second transistor and to ground.

7. The electronic device of claim 4, wherein the first node of the primary winding of the transformer is coupled to the oscillation control stage and the second node of the primary winding of the transformer is coupled to ground, and wherein the switching stage comprises a first transistor having a collector node, a base node and an emitter node, and a second transistor having a collector node, a base node and an emitter node, wherein the emitter nodes of the first and second transistors are coupled, the collector node of the first transistor is coupled to the output node of the voltage reducer, and the collector node of the second transistor is coupled to the first node of the primary winding of the transformer, and wherein the oscillation control stage provides a first oscillation control signal to the base node of the first transistor and a second oscillation control signal to the base node of the second transistor.

8. The electronic device of claim 7, wherein the oscillation control stage comprises:
k) a first resistor having first and second nodes, the first node being coupled to the base node of the second transistor for providing the second oscillation control signal, and the second node being coupled to ground;
l) a second resistor having first and second nodes, the first node of the second resistor being coupled to the collector node of the first transistor and to the output node of the voltage reducer, and the second node of the second resistor being coupled to the base node of the first transistor for providing the first oscillation control signal; and,
m) a capacitor having first and second nodes, the first node of the first capacitor being coupled to the base node of the first transistor and the second node of the second resistor, and the second node of the first capacitor being coupled to the collector node of the second transistor and the first node of the primary winding of the transformer.

9. The electronic device of claim 2, wherein the control block comprises:
g) a voltage regulator coupled to the standby power supply block, the voltage regulator receives the second power supply signal and produces a regulator output voltage to power components of the control block;
h) a voltage conversion stage coupled to the voltage regulator, the voltage conversion stage receives the regulator output voltage and generates a reference voltage;
i) a detection circuit coupled to the voltage regulator and the voltage conversion stage, the detection circuit processes the mode control signal and generates a detection signal; and,
j) a control circuit coupled to the voltage regulator, the voltage conversion stage, the detection circuit and the coupling unit, the control circuit receives the detection signal and produces at least one signal indicating the mode of operation including the coupling signal, the control circuit also including circuitry for preventing false transitions on the coupling signal.

10. The electronic device of claim 9, wherein the detection circuit comprises:
k) an amplification stage for amplifying the detection signal;
l) a filtering stage coupled to the amplification stage, the filtering stage high-pass filters the amplified detection signal;
m) a comparator stage coupled to the filtering stage, the comparator stage compares the filtered detection signal with a comparison voltage to determine whether the mode control signal is indicative of full operation mode or standby operation mode; and,
n) a switching stage coupled to the first comparator stage, the switching stage receives the output of the first comparator stage and generates the detection signal, the switching stage including circuitry for providing timing transitions on the detection signal.

11. The electronic device of claim 9, wherein the control circuit comprises:
k) a first comparator stage that receives the detection signal and compares the detection signal with a second comparison voltage to determine whether the mode control signal is indicative of full operation mode or standby operation mode; and,
l) a first output stage coupled to the first comparator stage and the coupling unit, the first output stage generates the coupling signal based on the output of the first comparator stage and provides the coupling signal to the coupling unit.

12. The electronic device of claim 11, wherein the control circuit further comprises:
m) a second comparator stage coupled to the first comparator stage, the second comparator stage receives the detection signal and compares the detection signal with the second comparison voltage to obtain an opposite result compared to the first comparator stage;
n) a feedback stage coupled to the second comparator stage and a switching stage of the detection circuit, the feedback stage provides a feedback signal to the switching stage for preventing false transitions in the detection signal; and,
o) a second output stage coupled to the second comparator and the coupling unit, the second indication stage providing power to the coupling unit.

13. The electronic device of claim 12, wherein the first output stage generates a first indication signal and the second output stage generates a second indication signal, the first and second indication signals providing an indication of the operation mode.

14. The electronic device of claim 2, wherein the application circuit includes an audio amplifier connected to the main power supply circuit for receiving the first power supply signal and a speaker connected to the audio amplifier, and the mode control signal is an input audio signal.

15. A standby circuit that generates a control signal for configuring a main power supply circuit to operate in one of a full operation mode and a standby operation mode, wherein the standby circuit comprises:
a) a standby power supply block comprising:
i) a voltage reducer that receives a first supply voltage and produces a reduced voltage;
ii) a transformer having a primary winding and a secondary winding, the primary winding having first and second nodes, the primary winding receiving a switched version of the reduced voltage, and the secondary winding producing a power supply signal;
iii) a switching stage coupled to the primary winding of the transformer for providing an oscillation signal to switch the voltage across the primary winding based on a switching sequence; and,
iv) an oscillation control stage coupled to the voltage reducer and the switching stage, the oscillation control stage receives the reduced voltage and produces at least one oscillation control signal to control the switching of the switching stage, wherein the switching stage provides the oscillation signal as feedback to the oscillation control stage for altering the at least one oscillation control signal; and,
b) a control block coupled to the standby power supply block to receive the power supply signal, the control block receives a mode control signal that indicates the operation mode and generates a coupling signal based on the mode indicated by the mode control signal, the control signal being based on the coupling signal.

16. The standby circuit of claim 15, wherein the first node of the primary winding of the transformer is coupled to the voltage reducer and wherein the switching stage comprises a first transistor having a collector node, a base node and an emitter node, and a second transistor having a collector node, a base node and an emitter node, wherein the emitter nodes of the first and second transistors are coupled, the collector node of the first transistor is coupled to the second node of the primary winding of the transformer, and the collector node of the second transistor is coupled to the oscillation control stage and to ground, and wherein the oscillation control stage provides a first oscillation control signal to the base node of the first transistor and a second oscillation control signal to the base node of the second transistor.

17. The standby circuit of claim 16, wherein the oscillation control stage comprises:
c) a first resistor having first and second nodes, the first node being coupled to the output of the voltage reducer to receive the reduced voltage and the second node being coupled to the base node of the first transistor for providing the first oscillation control signal;
d) a capacitor having first and second nodes, the first node of the capacitor being coupled to the collector node of the first transistor and the second node of the capacitor being coupled to the base node of the second transistor; and,
e) a second resistor having first and second nodes, the first node of the second resistor being coupled to the second node of the capacitor and to the base node of the second transistor to provide the second oscillation control signal, and the second node of the second resistor being coupled to the collector node of the second transistor and to ground.

18. The electronic device of claim 15, wherein the first node of the primary winding of the transformer is coupled to the oscillation control stage and the second node of the primary winding of the transformer is coupled to ground, and wherein the switching stage comprises a first transistor having a collector node, a base node and an emitter node, and a second transistor having a collector node, a base node and an emitter node, wherein the emitter nodes of the first and second transistors are coupled, the collector node of the first transistor is coupled to the output node of the voltage reducer, and the collector node of the second transistor is coupled to the first node of the primary winding of the transformer, and wherein the oscillation control stage provides a first oscillation control signal to the base node of the first transistor and a second oscillation control signal to the base node of the second transistor.

19. The electronic device of claim 18, wherein the oscillation control stage comprises:
c) a first resistor having first and second nodes, the first node being coupled to the base node of the second transistor for providing the second oscillation control signal, and the second node being coupled to ground;
d) a second resistor having first and second nodes, the first node of the second resistor being coupled to the collector node of the first transistor and to the output node of the voltage reducer, and the second node of the second resistor being coupled to the base node of the first transistor for providing the first oscillation control signal; and,
e) a capacitor having first and second nodes, the first node of the first capacitor being coupled to the base node of the first transistor and the second node of the second resistor, and the second node of the first capacitor being coupled to the collector node of the second transistor and the first node of the primary winding of the transformer.

20. The standby circuit of claim 15, wherein the switching sequence switches at a frequency of approximately 50 kHz or less.

21. The standby circuit of claim 15, wherein the voltage reducer includes a resistive portion and a capacitive portion, and the output node of the voltage reducer is between the resistive and capacitive portions and provides the reduced voltage.

22. The standby circuit of claim 21, wherein the reduced voltage is approximately 50 Volts.

23. The standby circuit of claim 15, wherein the control block comprises:
c) a voltage regulator coupled to the standby power supply block, the voltage regulator receives the second power supply signal and produces a regul 7 ator output voltage to power components of the control block;
d) a voltage conversion stage coupled to the voltage regulator, the voltage conversion stage receives the regulator output voltage and generates a reference voltage;
e) a detection circuit coupled to the voltage regulator and the voltage conversion stage, the detection circuit processes the mode control signal and generates a detection signal; and,
f) a control circuit coupled to the voltage regulator, the voltage conversion stage, and the detection circuit, the control circuit receives the detection signal and produces at least one signal indicating the mode of operation including the coupling signal, the control circuit also including circuitry for preventing false transitions on the coupling signal.

24. The standby circuit of claim 23, wherien the standby circuit further includes A coupling unit connected to the control circuit, the coupling unit recieves the coupling signal and generates the control signal.

25. The standby circuit of claim 24, wherien the detection circuit comprises:
g) An amplification stage for amplifying the detection signal;
h) a filtering stage coupled to the amplification stage, the filtering stage high-pass filters amplified detection signal;
i) A comparator stage coupled to filtering stage, the comparator stage compares the filtered detection signal with a comparison voltage to determine whwther the mode control signal is indicative of full operation mode or standby operation mode; and,
j) A switching stage coupled to the first comparator stage and the switching stage receives the output of the first comparator stage and generates the detection signal, and the switching stage further including circuity for providing timing transitions on the detection signal.

26. The standby circuit of claim 24, wherein the control circuit comprises:
g) a first comparator stage that receives the detection signal and compares the detection signal with a second comparison voltage to determine whether the mode control signal is indicative of full operation mode or standby operation mode; and,
h) a first output stage coupled to the first comparator stage and the coupling unit, the first output stage generates the coupling signal based on the output of the first comparator stage and provides the coupling signal to the coupling.

27. The standby circuit of claim 26, wherein the control circuit further comprises:
i) a second comparator stage coupled to the first comparator stage, the second comparator stage receives the detection signal and compares the detection signal with the second comparison voltage to obtain an opposite result compared to the first comparator stage;
j) a feedback stage coupled to the second comparator stage and a switching stage of the detection circuit, the feedback stage provides a feedback signal to the switching stage for preventing false transitions in the detection signal; and,
o) a second output stage coupled to the second comparator and the coupling unit, the second indication stage providing power to the coupling unit.

28. The standby circuit of claim 27, wherein the first output stage generates a first indication signal and the second output stage generates a second indication signal, the first and second indication signals providing an indication of the operation mode.

29. A standby circuit that generates a control signal for configuring a main power supply circuit to operate in one of a full operation mode and a standby operation mode, wherein the standby circuit comprises:
a) a standby power supply block for producing a power supply signal based on a rectified voltage signal, the standby power supply block including a transformer with a primary winding and a secondary winding, the primary winding receiving an oscillating version of the rectified voltage signal, and the secondary winding producing the power supply signal, the standby power supply block further including an oscillation block that provides the oscillating version of the rectified voltage signal to the primary winding of the transformer, wherein the oscillation block uses the oscillation signal as feedback for adjusting the oscillation signal; and,
b) a control block coupled to the standby power supply block to receive the power supply signal, the control block receives a mode control signal that indicates the operation mode and generates a coupling signal based on the mode indicated by the mode control signal, the control signal being based on the coupling signal.
